(19) United States
(12) Patent Application Publication
(10) Pub. No.: US 2025/0215122 A1
(43) Pub. Date: Jul. 3, 2025

(54) CURABLE COMPOSITION FOR 3D PRINTING PROCESS AND 3D-PRINTED OBJECT FORMED THEREFROM AND 3D PRINTING PROCESS USING THE SAME

(71) Applicant: BASF SE, Ludwigshafen am Rhein (DE)

(72) Inventors: Fan ZHANG, Shanghai (CN); Zhi Zhong CAI, Shanghai (CN); Jie LU, Shanghai (CN)

(21) Appl. No.: 18/853,863

(22) PCT Filed: Mar. 31, 2023
(86) PCT No.: PCT/EP2023/058493

§ 371 Date: Oct. 3, 2024

(30) Foreign Application Priority Data
Apr. 6, 2022 (WO) PCT/CN2022/085332

(51) Int. Cl. C08F 20/10; B33Y 70/00

(52) U.S. Cl. CPC C08F 20/10; B33Y 70/00

(57) ABSTRACT

The present invention relates to a curable composition, which comprises: (A) at least one component containing an ethylenically unsaturated group, wherein component (A) comprises a component (A1) containing a structure (K) selected from an isocyanurate structure and/or a tricyclodecane ring structure; and (B) at least one photo-initiator, wherein the average glass transition temperature (Tg,av) calculated from the curable composition using the following Fox's equation is at least 373.15K, preferably at least 393.15K, more preferably at least 423.15K, wherein Tg,i is the glass transition temperature in Kelvin of the homopolymer of component (i) constituting component (A), and w, is the mass fraction of component (i) in component (A); to a process of forming a 3D-printed object from the same and a 3D-printed object prepared therefrom. The 3D-printed object obtained from the curable composition of the present invention has high HDT and excellent mechanical performances.

$$\frac{1}{{T}_{g , av}} = \sum \frac{{w}_{i}}{{T}_{g , i}}$$

### TECHNICAL FIELD

The present invention relates to a composition for three-dimensional (hereinafter referred to as “3D”) printing. In particular, the present invention relates to a curable composition for 3D-printing. The present invention further relates to a process of forming a 3D-printed object by using the composition, and a 3D-printed object formed therefrom.

### BACKGROUND

3D-printing or additive manufacturing (AM) is a manufacturing method that seeks to avoid traditional manufacturing techniques that are either subtractive (i.e. machining and ablation) or formative (i.e. molding and casting). In addition, 3D-printing has considerable benefits in terms of design freedom. UV-curable photopolymer is a class of 3D-printable materials which have been widely used in various applications including prototyping of plastic parts, metal investment casting, dental applications, etc. Up to date, the UV-curable photopolymers on the market are suitable in making prototypes and demonstrations but generally are not adequate for real applications that require thermal and mechanical properties. To bridge the gap from prototyping to real manufacturing, it is critical to have advanced materials with specific properties dictated by targeted industrial applications.

Automotive industry is one of the most important consuming sectors of polymers. The growing demand on fuel efficiency and light weighting has made 3D-printing a promising technique to manufacture plastic components within a vehicle, such as interior parts, connectors and functional prototypes. These applications usually require the materials possessing adequate heat deflection temperature (HDT) and mechanical performances, which is currently a challenging task.

Therefore, there is a strong need to provide curable compositions which will provide 3D-printed objects with high heat deflection temperature (HDT), at the same time having excellent mechanical performances.

### SUMMARY OF THE INVENTION

It is an object of the invention to provide a curable composition which comprises (A) at least one component containing an ethylenically unsaturated group, wherein component (A) comprises a component (A1) containing a structure (K) selected from an isocyanurate structure and/or a tricyclodecane ring structure. The cured product from the curable composition has high HDT and excellent mechanical performances, in particular it can reach a HDT of at least 100° C. under a load of 1.82 MPa, as measured according to the test standard ASTM D648-07, and will have excellent mechanical performances such as those especially suitable for the applications wherein high rigidity is needed.

Another object of the present invention is to provide a 3D-printed object formed from the curable composition of the present invention.

A further object of the present invention is to provide a process of forming 3D-printed object by using the curable composition of the present invention.

It has been surprisingly found that the above objects can be achieved by following embodiments:

1. A curable composition, which comprises:
(A) at least one component containing an ethylenically unsaturated group, wherein component (A) comprises a component (A1) containing a structure (K) selected from an isocyanurate structure and/or a tricyclodecane ring structure; and
(B) at least one photo-initiator,
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A).

2. The curable composition according to embodiment 1, wherein component (A1) contains at least 1 ethylenically unsaturated groups, preferably contains 1 to 5 ethylenically unsaturated groups, more preferably contains 2 to 4 ethylenically unsaturated groups.

3. The curable composition according to embodiment 1 or 2, wherein the ethylenically unsaturated group is selected from the group consisting of allyl, vinyl, acrylate, methacrylate, acryloxy, methacryloxy, acrylamido, methacrylamido, acetylenyl, and maleimido.

4. The curable composition according to any one of embodiments 1 to 3, wherein component (A1) comprises or is a tri(meth)acrylate of tris(hydroxy-C₁₋₃₀-alkyl) isocyanurates, preferably, component (A1) comprises or is tri(meth)acrylate of tris-(2-hydroxyethyl)isocyanurate, tri(meth)acrylate of tris(hydroxymethyl)isocyanurate, tri(meth)acrylate of tris(3-hydroxy-n-propyl)isocyanurate, or any combination thereof.

5. The curable composition according to any one of embodiments 1 to 4, wherein component (A1) comprises or is a tricyclodecane-di-C₁₋₂₀-alkanol di(meth)acrylate, preferably tricyclodecanedi-methanol di(meth)acrylate, tricyclodecanedi-ethanol di(meth)acrylate, tricyclodecanedi-propanol di(meth)acrylate, tricyclodecanedi-butanol di(meth)acrylate, or tricyclodecanedi-pentanol di(meth)acrylate.

6. The curable composition according to any one of embodiments 1 to 5, wherein the photo-initiator is a free radical photo-initiator and/or an ionic photo-initiator, preferably a free radical photo-initiator.

7. The curable composition of any one of embodiments 1 to 6, wherein the amount of component (A) is in the range from 80% to 99.9% by weight, preferably from 90% to 99.9% by weight, more preferably from 97% to 99.5% by weight, based on the total amount of the curable composition.

8. The curable composition according to any one of embodiments 1 to 7, wherein the amount of component (A1) is in the range from 10% to 90% by weight, preferably from 15% to 85% by weight, more preferably from 20% to 80% by weight, based on the total amount of component (A).

9. The curable composition according to any one of embodiments 1 to 8, wherein the amount of the photo-initiator is in the range from 0.1% to 8% by weight, preferably from 0.1% to 5% by weight, more preferably from 0.5% to 3% by weight, based on the total amount of the curable composition.

10. The curable composition according to any one of embodiments 1 to 9, which further comprises an auxiliary agent as component (C), such as surfactants, flame retardants, pigments, fillers, dyes, catalyst, UV absorbers and stabilizers, and reinforcing materials, preferably in an amount in the range from 0 to 18% by weight, preferably from 0 to 15% by weight, more preferably from 0 to 10% by weight, based on the total amount of the curable composition.

11. The curable composition according to any one of embodiments 1 to 10, wherein the cured product formed from the curable composition has a HDT value of at least 100° C., preferably at least 140° C., more preferably at least 190° C., at a load of 1.82 MPa, as measured according to the test standard ASTM D648-07.

12. The curable composition according to any one of embodiments 1 to 11, wherein component (A) further comprises a component (A2) containing no structure (K).

13. A process of forming a 3D-printed object, comprising using the curable composition according to any one of embodiments 1 to 12.

14. The process according to embodiment 13, comprising:
(i) applying the curable composition, and curing the applied curable composition layer by layer by radiation to form an intermediate 3D-printed object; and
(ii) curing the whole intermediate 3D-printed object by radiation to form a cured 3D-printed object.

15. The process according to embodiment 14, wherein stereolithography, photopolymer jetting, digital light processing, or LCD technology is used in step (i) to form the intermediate 3D-printed object.

16. The process according to embodiment 14 or 15, wherein the radiation is UV radiation.

17. A 3D-printed object formed from the curable composition according to any one of embodiments 1 to 12 or obtained by the process according to any one of embodiments 13 to 16.

18. The 3D-printed object according to embodiment 17, wherein the 3D-printed object comprises plastic parts within a vehicle, such as interior parts, connectors and functional prototypes.

The 3D-printed object obtained from the curable composition of the present invention has high HDT and excellent mechanical performances. In particular, it can reach a HDT of at least 100° C. under a load of 1.82 MPa, such as a HDT of at least 110° C., or at least 120° C., preferably at least 140° C., more preferably at least 190° C., at a load of 1.82 MPa, as measured according to the test standard ASTM D648-07, and will have excellent mechanical performances such as those especially suitable for the applications wherein high rigidity is needed.

### DETAILED DESCRIPTION OF THE INVENTION

Unless defined otherwise, all technical and scientific terms used herein have the meaning commonly understood by a person skilled in the art to which the invention belongs. As used herein, the following terms have the meanings ascribed to them below, unless specified otherwise.

The singular-form articles “a”, “an” and “the” mean one or more of the species designated by the term following said article.

Temperature in Celsius (° C.) and temperature in Kelvin (K) used in the present disclosure have a relationship of: T (K)=T (° C.)+273.15.

In the context of the present disclosure, any specific values mentioned for a feature (comprising the specific values mentioned in a range as the end point) can be recombined to form a new range.

Further embodiments of the present invention are discernible from the claims, the description, the examples, and the drawings. It will be understood that the aforementioned and hereinbelow still to be elucidated features of the subject matter of the present invention are utilizable not only in the particular combination indicated, but also in other combinations without leaving the realm of the present invention.

One aspect of the present invention relates to a curable composition, which comprises:
(A) at least one component containing an ethylenically unsaturated group, wherein component (A) comprises a component (A1) containing a structure (K) selected from an isocyanurate structure and/or a tricyclodecane ring structure; and
(B) at least one photo-initiator,
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A).

### Component (A)

The curable composition of the present invention comprises at least one component containing an ethylenically unsaturated group as component (A). In an embodiment of the invention, the ethylenically unsaturated group contains a carbon-carbon unsaturated bond, such as those found in the following functional groups: allyl, vinyl, acrylate, methacrylate, acryloxy, methacryloxy, acrylamido, methacrylamido, acetylenyl, maleimido, and the like.

The amount of component (A) can be in the range from 80 to 99.9% by weight, for example 80% by weight, 82% by weight, 84% by weight, 86% by weight, 88% by weight, 90% by weight, 92% by weight, 94% by weight, 96% by weight, 98% by weight, 99% by weight, 99.9% by weight, such as from 85 to 99.9% by weight, preferably 90 to 99.9% by weight, more preferably 95 to 99.9% by weight, or 97 to 99.5% by weight, based on the total weight of the curable composition of the present invention.

### Component (A1)

Component (A) of the present invention comprises a component (A1) containing an ethylenically unsaturated group and a structure (K) selected from an isocyanurate structure and/or a tricyclodecane ring structure. Preferably, component (A1) contains at least 1 ethylenically unsaturated groups, preferably contains 1 to 5 ethylenically unsaturated groups, more preferably contains 2 to 4 ethylenically unsaturated groups.

In a preferred embodiment of the invention, the ethylenically unsaturated group is selected from the group consisting of allyl, vinyl, acrylate, methacrylate, acryloxy, methacryloxy, acrylamido, methacrylamido, acetylenyl, and maleimido.

In an embodiment of the invention, component (A1) comprises or is a tri(meth)acrylate of tris(hydroxy-alkyl) isocyanurates, preferably a tri(meth)acrylate of tris(hydroxy-C₁₋₃₀-alkyl) isocyanurates.

Preferably, hydroxy-C₁₋₃₀-alkyl of the tri(meth)acrylate of tris(hydroxy-alkyl) isocyanurates is selected from hydroxy-methyl, hydroxy-ethyl, hydroxy-propyl, hydroxy-butyl, hydroxy-pentyl, hydroxy-hexyl, hydroxy-octyl, hydroxy-nonyl, hydroxy-decyl, hydroxy-C₁₁-alkyl, hydroxy-C₁₂-alkyl, hydroxy-C₁₃-alkyl, hydroxy-C₁₄-alkyl, hydroxy-C₁₅-alkyl, hydroxy-C₁₆-alkyl, hydroxy-C₁₇-alkyl, hydroxy-C₁₈-alkyl, hydroxy-C₁₉-alkyl, hydroxy-C₂₀-alkyl, hydroxy-C₂₁-alkyl, hydroxy-C₂₂-alkyl, hydroxy-C₂₃-alkyl, hydroxy-C₂₄-alkyl, hydroxy-C₂₅-alkyl, hydroxy-C₂₆-alkyl, hydroxy-C₂₇-alkyl, hydroxy-C₂₃-alkyl, hydroxy-C₂₉-alkyl, hydroxy-C₃₀-alkyl, more preferably, selected from hydroxy-methyl, hydroxy-ethyl, hydroxy-propyl, hydroxy-butyl, hydroxy-pentyl, hydroxy-hexyl, hydroxy-octyl, hydroxy-nonyl, and hydroxy-decyl.

Preferably, component (A1) comprises or is tri(meth)acrylate of tris-(2-hydroxyethyl)isocyanurate, tri(meth)acrylate of tris(hydroxymethyl)isocyanurate, tri(meth)acrylate of tris(3-hydroxy-n-propyl)isocyanurate, or any combination thereof.

In an embodiment of the invention, component (A1) comprises or is a tricyclodecane-di-alkanol di(meth)acrylate.

In a preferred embodiment of the invention, component (A1) comprises or is a tricyclodecanedi-C₁₋₂₀-alkanol di(meth)acrylate, such as tricyclodecanedi-methanol di(meth)acrylate, tricyclodecanedi-ethanol di(meth)acrylate, tricyclodecanedi-propanol di(meth)acrylate, tricyclodecanedi-butanol di(meth)acrylate, tricyclodecanedi-pentanol di(meth)acrylate, tricyclodecanedi-C₆-alkanol di(meth)acrylate, tricyclodecanedi-C₇-alkanol di(meth)acrylate, tricyclodecanedi-C₈-alkanol di(meth)acrylate, tricyclodecanedi-C₉-alkanol di(meth)acrylate, tricyclodecanedi-C₁₀-alkanol di(meth)acrylate, tricyclodecanedi-C₁₂-alkanol di(meth)acrylate, tricyclodecanedi-C₁₄-alkanol di(meth)acrylate, tricyclodecanedi-C₁₆-alkanol di(meth)acrylate, tricyclodecanedi-C₁₈-alkanol di(meth)acrylate, tricyclodecanedi-C₂₀-alkanol di(meth)acrylate, and any combination thereof. Preferably the tricyclodecane-di-C₁₋₂₀-alkanol di(meth)acrylate is tricyclodecanedi-methanol di(meth)acrylate, tricyclodecanedi-ethanol di(meth)acrylate, tricyclodecanedi-propanol di(meth)acrylate, tricyclodecanedi-butanol di(meth)acrylate, tricyclodecanedi-pentanol di(meth)acrylate, tricyclodecanedi-C₆-alkanol di(meth)acrylate, tricyclodecanedi-C₇-alkanol di(meth)acrylate, tricyclodecanedi-C₈-alkanol di(meth)acrylate, tricyclodecanedi-C₉-alkanol di(meth)acrylate, tricyclodecanedi-C₁₀-alkanol di(meth)acrylate.

In an embodiment of the invention, component (A1) may comprise or may be an isocyanurate having two or three allyl-alkyl as the ethylenically unsaturated groups or a tricyclodecane having one or two allyl-alkyl as the ethylenically unsaturated groups, such as an isocyanurate having two or three allyl-C₁₋₂₀ alkyl or a tricyclodecane having one or two allyl-C₁₋₂₀ alkyl. For example, the allyl-alkyl is selected from allyl-methyl, allyl-ethyl, allyl-propyl, allyl-butyl, allyl-pentyl, allyl-hexyl, allyl-octyl, allyl-nonyl, allyl-decyl, allyl-C₁₁-alkyl, allyl-C₁₂-alkyl, allyl-C₁₃-alkyl, allyl-C₁₄-alkyl, allyl-C₁₅-alkyl, allyl-C₁₆-alkyl, allyl-C₁₇-alkyl, allyl-C₁₈-alkyl, allyl-C₁₉-alkyl, and allyl-C₂₀-alkyl, more preferably, the allyl-alkyl is selected from allyl-methyl, allyl-ethyl, allyl-propyl, allyl-butyl, allyl-pentyl, allyl-hexyl, allyl-octyl, allyl-nonyl, and allyl-decyl. Preferably, the alkyl in the allyl-alkyl is interrupted by one or more heteroatoms, preferably one or two or three heteroatoms, such as O, N, or S, preferably O or N, at the end of the alkyl or in the middle of the alkyl; or the alkyl in the allyl-alkyl is interrupted by a group such as carbonyl group, amino group and acyloxy group, at the end of the alkyl or in the middle of the alkyl.

In a preferred embodiment of the invention, Sartomer SR368 available from Sartomer Co., Exton, PA., and Sartomer SR833S available from Sartomer Co., Exton, PA, are useful as component (A1) of the present invention.

The amount of component (A1) can be in the range from 10 to 90% by weight, for example 15% by weight, 20% by weight, 25% by weight, 30% by weight, 35% by weight, 40% by weight, 45% by weight, 50% by weight, 55% by weight, 60% by weight, 70% by weight, 80% by weight, 85% by weight, 90% by weight, preferably from 10 to 85% by weight, or 15 to 85% by weight, or 20 to 85% by weight, or 25 to 85% by weight, or 30 to 85% by weight, or 10 to 80% by weight, or 15 to 80% by weight, or 20 to 80% by weight, or 25 to 80% by weight, or 30 to 80% by weight, based on the total amount of component (A) of the present invention.

### Component (A2)

Preferably, component (A) of the present invention further comprises a component (A2). Component (A2) of the present invention contains an ethylenically unsaturated group, but contains no structure (K). In a preferred embodiment of the invention, the ethylenically unsaturated group is selected from the group consisting of allyl, vinyl, acrylate, methacrylate, acryloxy, methacryloxy, acrylamido, methacrylamido, acetylenyl, maleimido, and the like.

In an embodiment of the invention, component (A2) of the present invention contains, in addition to the ethylenically unsaturated group, urethane groups, ether groups, ester groups, carbonate groups, and any combination thereof.

In an embodiment of the present invention, component (A2) of the present invention comprises a monomer and/or oligomer containing an ethylenically unsaturated group.

Component (A2) of the present invention may comprise oligomers containing a core structure linked to the ethylenically unsaturated group, optionally via a linking group, wherein the core structure neither is structure (K) nor contains structure (K). The linking group can be an ether, ester, amide, urethane, or carbonate group that contains no structure (K). In some instances, the linking group is part of the ethylenically unsaturated group, for instance an acryloxy or acrylamido group. The core group can be an alkyl (straight and branched chain alkyl groups), aryl (e.g., phenyl), polyether, polyester, siloxane, urethane, or other core structures and oligomers thereof.

In some embodiments, as component (A2) of the present invention, the oligomer having an ethylenically unsaturated group can be selected from the following classes: urethane (i.e. an urethane-based oligomer having ethylenically unsaturated group), polyether (i.e. an polyether-based oligomer having ethylenically unsaturated group), polyester (i.e. an polyester-based oligomer having ethylenically unsaturated group), polycarbonate (i.e. an polycarbonate-based oligomer having ethylenically unsaturated group), polyestercarbonate (i.e. an polyestercarbonate-based oligomer having ethylenically unsaturated group), epoxy (i.e. an epoxy-based oligomer having ethylenically unsaturated group), silicone (i.e. a silicone-based oligomer having ethylenically unsaturated group) or any combination thereof. Preferably, the oligomer having an ethylenically unsaturated group can be selected from the following classes: a urethane-based oligomer, an epoxy-based oligomer, a polyester-based oligomer, a polyether-based oligomer, polyether urethane-based oligomer, polyester urethane-based oligomer or a silicone-based oligomer, as well as any combination thereof.

In a preferred embodiment of the invention, as component (A2) of the present invention, the oligomer having an ethylenically unsaturated group comprises a urethane-based oligomer having urethane repeating units and one, two or more ethylenically unsaturated groups, for example those containing carbon-carbon unsaturated double bond, such as (meth)acrylate groups, (meth)acrylamide groups, allyl groups and vinyl groups. Preferably, the oligomer contains at least one urethane linkage (for example, one, two or more urethane linkages) within the backbone of the oligomer molecule and at least one acrylate and/or methacrylate functional groups (for example, one, two or more acrylate and/or methacrylate functional groups) pendent to the oligomer molecule. In some embodiments, aliphatic, cycloaliphatic, or mixed aliphatic and cycloaliphatic urethane repeating units are suitable. Urethanes are typically prepared by the condensation of a diisocyanate with a diol. Aliphatic urethanes having at least two urethane moieties per repeating unit are useful. In addition, the diisocyanate and diol used to prepare the urethane comprise divalent aliphatic groups that may be the same or different.

In one embodiment, as component (A2) of the present invention, the oligomer having an ethylenically unsaturated group comprises polyester urethane-based oligomer or polyether urethane-based oligomer having at least one ethylenically unsaturated group. The ethylenically unsaturated group can be those containing carbon-carbon unsaturated double bond, such as acrylate groups, methacrylate groups, vinyl groups, allyl groups, acrylamide groups, methacrylamide groups etc., preferably acrylate groups and methacrylate groups.

Suitable urethane-based oligomers are known in the art and may be readily synthesized by a number of different procedures. For example, a polyfunctional alcohol may be reacted with a polyisocyanate (preferably, a stoichiometric excess of polyisocyanate) to form an NCO-terminated pre-oligomer, which is thereafter reacted with a hydroxy-functional ethylenically unsaturated monomer, such as hydroxy-functional (meth)acrylate. The polyfunctional alcohol may be any compound containing two or more OH groups per molecule and may be a monomeric polyol (e.g., a glycol), a polyester polyol, a polyether polyol or the like. The urethane-based oligomer in one embodiment of the invention is an aliphatic urethane-based oligomer having (meth)acrylate functional group.

Suitable polyether or polyester urethane-based oligomers include the reaction product of an aliphatic or aromatic polyether or polyester polyol with an aliphatic or aromatic polyisocyanate that is functionalized with a monomer containing the ethylenically unsaturated group, such as (meth)acrylate group. In a preferred embodiment, the polyether and polyester are aliphatic polyether and polyester, respectively. In a preferred embodiment, the polyether and polyester urethane-based oligomers are aliphatic polyether and polyester urethane-based oligomers and comprise (meth)acrylate group.

In one embodiment, as component (A2) of the present invention, the oligomer having an ethylenically unsaturated group may have a viscosity at 60° C. of in the range from 2000 to 100000 cP, for example 3000 cP, 4000 cP, 5000 cP, 6000 cP, 7000 cP, 8000 cP, 10000 cP, 20000 cP, 30000 cP, 40000 cP, 50000 cP, 60000 cP, 70000 cP, 80000 cP, 90000 cP, 95000 cP, preferably 4000 to 60000 cP, for example 4000 to 15000 cP, or 20000 cP to 60000 cP, as measured according to DIN EN ISO 3219.

The monomer can lower the viscosity of the curable composition of the invention. As component (A2) of the present invention, the monomer can be monofunctional or multifunctional (such as difunctional, trifunctional). In one embodiment, the monomer can be selected from the group consisting of (meth)acrylate monomers, (meth)acrylamide monomers, vinylaromatics having up to 20 carbon atoms, vinyl esters of carboxylic acids having up to 20 carbon atoms, α,β-unsaturated carboxylic acids having 3 to 8 carbon atoms and their anhydrides.

In the context of the present disclosure, term “(meth)acrylate monomer” means a monomer comprises a (meth)acrylate moiety. The structure of the (meth)acrylate moiety is as follows:

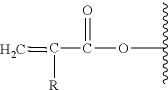

wherein R is H or methyl.

As component (A2) of the present invention, the (meth)acrylate monomer can be monofunctional or multifunctional (such as difunctional, trifunctional) (meth)acrylate monomer. Exemplary (meth)acrylate monomer can include C₁ to C₂₀ alkyl (meth)acrylate, C₁ to C₁₀ hydroxyalkyl (meth)acrylate, caprolactone (meth)acrylate, phenyl (meth)acrylate, benzyl (meth)acrylate, and phenethyl (meth)acrylate.

Specific examples of C₁ to C₂₀ alkyl (meth)acrylate can include methyl (meth)acrylate, ethyl (meth)acrylate, isopropyl (meth)acrylate, n-propyl (meth)acrylate, n-butyl (meth)acrylate, isobutyl (meth)acrylate, tert-butyl (meth)acrylate, sec-butyl (meth)acrylate, pentyl (meth)acrylate, n-hexyl (meth)acrylate, octyl (meth)acrylate, isooctyl (meth)acrylate, 2-ethylhexyl (meth)acrylate, decyl (meth)acrylate, isodecyl (meth)acrylate, n-lauryl (meth)acrylate, n-tridecyl (meth)acrylate, n-cetyl (meth)acrylate, n-stearyl (meth)acrylate, isomyristyl (meth)acrylate, stearyl (meth)acrylate, and isostearyl (meth)acrylate (ISTA). C₆ to C₁₈ alkyl (meth)acrylate, especially C₆ to C₁₆ alkyl (meth)acrylate or C₈ to C₁₂ alkyl (meth)acrylate is preferred.

Specific examples of C₁ to C₁₀ hydroxyalkyl (meth)acrylate, such as C₂ to C₈ hydroxyalkyl (meth)acrylate can include 2-hydroxyethyl (meth)acrylate, 2-hydroxypropyl (meth)acrylate, 3-hydroxypropyl (meth)acrylate, 3-hydroxybutyl (meth)acrylate, 4-hydroxybutyl (meth)acrylate, 6-hydroxyhexyl (meth)acrylate, or 3-hydroxy-2-ethylhexyl (meth)acrylate etc.

In the context of the present disclosure, term “(meth)acrylamide monomer” means a monomer comprises a (meth)acrylamide moiety. The structure of the (meth)acrylamide moiety is as follows: CH₂═CR¹—CO—N, wherein R¹ is hydrogen or methyl. Specific example of (meth)acrylamide monomer can include N-(hydroxymethyl)acrylamide, N-hydroxyethyl acrylamide, N-isopropylacrylamide, N-isopropylmethacrylamide, N-tert-butylacrylamide, N,N′-methylenebisacrylamide, N-(isobutoxymethyl)acrylamide, N-(butoxymethyl)acrylamide, N-[3-(dimethylamino)propyl]methacrylamide, N,N-dimethylacrylamide, N,N-diethylacrylamide, N-(hydroxymethyl)methacrylamide, N-hydroxyethyl methacrylamide, N-isopropylmethacrylamide, N-isopropylmethacrylamide, N-tert-butylmethacrylamide, N,N′-methylenebismethacrylamide, N-(isobutoxymethyl)methacrylamide, N-(butoxymethyl)methacrylamide, N-[3-(dimethylamino)propyl]methacrylamide, N,N-dimethylmethacrylamide and N,N-diethylmethacrylamide. The (meth)acrylamide monomer can be used alone or in combination.

Examples of vinylaromatics having up to 20 carbon atoms can include, such as styrene and C₁-C₄-alkyl substituted styrene, such as vinyltoluene, p-tert-butylstyrene and α-methyl styrene.

Examples of vinyl esters of carboxylic acids having up to 20 carbon atoms (for example 2 to 20 or 8 to 18 carbon atoms) can include vinyl laurate, vinyl stearate, vinyl propionate, and vinyl acetate.

Example of α,β-unsaturated carboxylic acids having 3 to 8 carbon atoms can be acrylic acid or methacrylic acid.

Preferred monomers are (meth)acrylate monomer, (meth)acrylamide monomer, and vinylaromatics having up to 20 carbon atoms.

In a preferred embodiment, component (A2) of the present invention comprises both the oligomer and the monomer containing an ethylenically unsaturated group. The weight ratio of the oligomer to the monomer can be in the range from 10:1 to 1:10, preferably from 8:1 to 1:8, or from 5:1 to 1:5, or from 3:1 to 1:5, or from 1:1 to 1:4.

In a preferred embodiment of the invention, component (A2) of the present invention is selected from a group consisting of Rahn Genomer 4247 available from Rahn, Dymax BR952 available from Dymax, Acryloylmorpholine (ACMO) available from Rahn; and Isobornyl Methacrylate (IBOMA) available from Miwon.

### Photo-Initiator (B)

The curable composition of the present invention comprises at least one photo-initiator as component (B). For example, photo-initiator component (B) may include at least one free radical photo-initiator and/or at least one ionic photo-initiator, and preferably at least one (for example one or two) free radical photo-initiator. It is possible to use all photo-initiators known in the art for use in compositions for 3D-printing, e.g., it is possible to use photo-initiators that are known in the art suitable for stereolithography (SLA), digital light processing (DLP) and photopolymer jetting (PPJ) processes.

As examples of the photo-initiator for the present invention, it is possible to use those referred to in “Advances in Polymer Science”, Volume 14, Springer Berlin 1974 or in K. K. Dietliker, Chemistry and Technology of UV and EB Formulation for Coatings, Inks and Paints, Volume 3; Photo-initiators for Free Radical and Cationic Polymerization, P. K. T. Oldring (Ed.), SITA Technology Ltd, London.

Suitable examples include phosphine oxides, benzophenones, α-hydroxyalkyl aryl ketones, thioxanthones, anthraquinones, acetophenones, benzoins and benzoin ethers, ketals, imidazoles or phenylglyoxylic acids, and mixtures thereof.

Phosphine oxides are for example monoacyl- or bisacylphosphine oxides, such as Irgacure®819 (bis(2,4,6-trimethylbenzoyl)phenylphosphine oxide), as described for example in EP-A 7 508, EP-A 57 474, DE-A 196 18 720, EP-A 495 751 or EP-A 615 980, such as 2,4,6-trimethylbenzoyldiphenylphosphine oxide (Lucirin® TPO), ethyl 2,4,6-trimethylbenzoylphenylphosphinate or
bis(2,6-dimethoxybenzoyl)-2,4,4-trimethylpentylphosphine oxide;
Benzophenones are for example benzophenone, 4-aminobenzophenone,
4,4′-bis(dimethylamino)benzophenone, 4-phenylbenzophenone,
4-chlorobenzophenone, Michler's ketone, o-methoxybenzophenone,
2,4,6-trimethylbenzophenone, 4-methylbenzophenone, 2,4-dimethylbenzophenone,
4-isopropylbenzophenone, 2-chlorobenzophenone, 2,2′-dichlorobenzophenone,
4-methoxybenzophenone, 4-propoxybenzophenone or 4-butoxybenzophenone;
α-hydroxyalkyl aryl ketones are for example 1-benzoylcyclohexan-1-ol
(1-hydroxycyclohexyl phenyl ketone), 2-hydroxy-2,2-dimethylacetophenone
(2-hydroxy-2-methyl-1-phenylpropan-1-one), 1-hydroxyacetophenone,
1-[4-(2-hydroxyethoxy)phenyl]-2-hydroxy-2-methyl-1-propan-1-one or polymer containing 2-hydroxy-2-methyl-1-(4-isopropen-2-ylphenyl)propan-1-one in copolymerized form (Esacure® KIP 150);
Xanthones and thioxanthones are for example 10-thioxanthenone, thioxanthen-9-one,
xanthen-9-one, 2,4-dimethylthioxanthone, 2,4-diethylthioxanthone,
2,4-diisopropylthioxanthone, 2,4-dichlorothioxanthone or chloroxanthenone;
Anthraquinones are for example β-methylanthraquinone, tert-butylanthraquinone, anthraquinonecarboxylic esters, benz[de]anthracen-7-one,
benz[a]anthracen-7,12-dione, 2-methylanthraquinone, 2-ethylanthraquinone,
2-tert-butylanthraquinone, 1-chloroanthraquinone or 2-amylanthraquinone;
Acetophenones are for example acetophenone, acetonaphthoquinone,
valerophenone, hexanophenone, α-phenylbutyrophenone,
p-morpholinopropiophenone, dibenzosuberone, 4-morpholinobenzophenone,
p-diacetylbenzene, 4′-methoxyacetophenone, α-tetralone, 9-acetylphenanthrene,
2-acetylphenanthrene, 3-acetylphenanthrene, 3-acetylindole, 9-fluorenone,
1-indanone, 1,3,4-triacetylbenzene, 1-acetonaphthone, 2-acetonaphthone,
2,2-dimethoxy-2-phenylacetophenone, 2,2-diethoxy-2-phenylacetophenone,
1,1-dichloroacetophenone, 1-hydroxyacetophenone, 2,2-diethoxyacetophenone,
2-methyl-1-[4-(methylthio)phenyl]-2-morpholinopropan-1-one,
2,2-dimethoxy-1,2-diphenylethan-2-one or
2-benzyl-2-dimethylamino-1-(4-morpholinophenyl)butan-1-one;
Benzoins and benzoin ethers are for example 4-morpholinodeoxybenzoin, benzoin,
benzoin isobutyl ether, benzoin tetrahydropyranyl ether, benzoin methyl ether,
benzoin ethyl ether, benzoin butyl ether, benzoin isopropyl ether or 7H-benzoin methyl ether; and
Ketals are for example acetophenone dimethyl ketal, 2,2-diethoxyacetophenone, or benzil ketals, such as benzil dimethyl ketal.

Phenylglyoxylic acids are described for example in DE-A 198 26 712, DE-A 199 13 353 or WO 98/33761.

Photo-initiators which can be used as well are for example benzaldehyde, methyl ethyl ketone, 1-naphthaldehyde, triphenylphosphine, tri-o-tolylphosphine or 2,3-butaned-ione.

Appropriate mixtures of photo-initiators may also be used. Typical mixtures include for example:
2-hydroxy-2-methyl-1-phenylpropan-2-one and 1-hydroxycyclohexyl phenyl ketone;
bis(2,6-dimethoxybenzoyl)-2,4,4-trimethylpentylphosphine oxide and
2-hydroxy-2-methyl-1-phenylpropan-1-one;
benzophenone and 1-hydroxycyclohexyl phenyl ketone;
bis(2,6-dimethoxybenzoyl)-2,4,4-trimethylpentylphosphine oxide and
1-hydroxycyclohexyl phenyl ketone;
2,4,6-trimethylbenzoyldiphenylphosphine oxide and
2-hydroxy-2-methyl-1-phenylpropan-1-one;
2,4,6-trimethylbenzophenone and 4-methylbenzophenone; or
2,4,6-trimethylbenzophenone, and 4-methylbenzophenone and
2,4,6-trimethylbenzoyldiphenylphosphine oxide.

The amount of the photo-initiator (B) can be in the range from 0.1 to 8% by weight, for example 0.2% by weight, 0.3% by weight, 0.4% by weight, 0.5% by weight, 0.6% by weight, 0.7% by weight, 0.8% by weight, 0.9% by weight, 1% by weight, 2% by weight, 3% by weight, 4% by weight, 5% by weight, 6% by weight, 7% by weight, or 8% by weight, preferably from 0.1 to 7% by weight, or 0.1 to 6% by weight, or 0.1 to 5% by weight, more preferably 0.4 to 6% by weight, or 0.4 to 5% by weight, or 0.5 to 5% by weight, or 0.5 to 3% by weight based on the total weight of the curable composition of the present invention.

Curable Composition The curable composition of the present invention comprises:
(A) at least one component containing an ethylenically unsaturated group, wherein component (A) comprises a component (A1) containing a structure (K) selected from an isocyanurate structure and/or a tricyclodecane ring structure; and
(B) at least one photo-initiator,
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A).

Preferably, component (A) further comprises a component (A2) containing no structure (K).

It is surprisingly found that, with the curable composition of the present invention, the cured product obtained therefrom have a high HDT and excellent mechanical performances. Especially, the cured product obtained from the curable composition of the present invention can reach a HDT of at least 100° C., preferably at least 140° C., more preferably at least 190° C., at a load of 1.82 MPa, as measured according to the test standard ASTM D648-07, and will have excellent mechanical performances such as those especially suitable for the applications wherein high rigidity is needed.

In one embodiment, the curable composition of the present invention comprises:
(A) 80% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 8% by weight of at least one photo-initiator, wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A).

In one embodiment, the curable composition of the present invention comprises:
(A) 90% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 5% by weight of at least one photo-initiator,
wherein the amount of component (A1) is in the range from 10% to 90% by weight, preferably from 15% to 85% by weight, more preferably from 20% to 80% by weight,
based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A).

In one embodiment, the curable composition of the present invention comprises:
(A) 97% to 99.5% by weight of at least one component containing an ethylenically unsaturated group, wherein component (A) comprises a component (A1) containing a structure (K) selected from an isocyanurate structure and/or a tricyclodecane ring structure; and
(B) 0.1% to 3% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A).

In one embodiment, the curable composition of the present invention comprises:
(A) 80% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 8% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
   wherein component (A1) comprises or is a tri(meth)acrylate of tris(hydroxy-C₁₋₃₀-alkyl) isocyanurates,
   the hydroxy-C₁₋₃₀-alkyl of the tri(meth)acrylate of tris(hydroxy-alkyl) isocyanurates is selected from hydroxy-methyl, hydroxy-ethyl, hydroxy-propyl, hydroxy-butyl, hydroxy-pentyl, hydroxy-hexyl, hydroxy-octyl, hydroxy-nonyl, hydroxy-decyl, hydroxy-C₁₁-alkyl, hydroxy-C₁₂-alkyl, hydroxy-C₁₃-alkyl, hydroxy-C₁₄-alkyl, hydroxy-C₁₅-alkyl, hydroxy-C₁₆-alkyl, hydroxy-C₁₇-alkyl, hydroxy-C₁₈-alkyl, hydroxy-C₁₉-alkyl, hydroxy-C₂₀-alkyl, hydroxy-C₂₁-alkyl, hydroxy-C₂₂-alkyl, hydroxy-C₂₃-alkyl, hydroxy-C₂₄-alkyl, hydroxy-C₂₅-alkyl, hydroxy-C₂₆-alkyl, hydroxy-C₂₇-alkyl, hydroxy-C₂₃-alkyl, hydroxy-C₂₆-alkyl, hydroxy-C₃₀-alkyl, preferably selected from hydroxy-methyl, hydroxy-ethyl, hydroxy-propyl, hydroxy-butyl, hydroxy-pentyl, hydroxy-hexyl, hydroxy-octyl, hydroxy-nonyl, and hydroxy-decyl.

In one embodiment, the curable composition of the present invention comprises:
(A) 90% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 5% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
   wherein component (A1) comprises or is a tri(meth)acrylate of tris(hydroxy-C₁₋₃₀-alkyl) isocyanurates,
   the hydroxy-C₁₋₃₀-alkyl of the tri(meth)acrylate of tris(hydroxy-alkyl) isocyanurates is selected from hydroxy-methyl, hydroxy-ethyl, hydroxy-propyl, hydroxy-butyl, hydroxy-pentyl, hydroxy-hexyl, hydroxy-octyl, hydroxy-nonyl, hydroxy-decyl, hydroxy-C₁₁-alkyl, hydroxy-C₁₂-alkyl, hydroxy-C₁₃-alkyl, hydroxy-C₁₄-alkyl, hydroxy-C₁₅-alkyl, hydroxy-C₁₆-alkyl, hydroxy-C₁₇-alkyl, hydroxy-C₁₈-alkyl, hydroxy-C₁₉-alkyl, hydroxy-C₂₀-alkyl, hydroxy-C₂₁-alkyl, hydroxy-C₂₂-alkyl, hydroxy-C₂₃-alkyl, hydroxy-C₂₄-alkyl, hydroxy-C₂₅-alkyl, hydroxy-C₂₆-alkyl, hydroxy-C₂₇-alkyl, hydroxy-C₂₃-alkyl, hydroxy-C₂₉-alkyl, hydroxy-C₃₀-alkyl, preferably selected from hydroxy-methyl, hydroxy-ethyl, hydroxy-propyl, hydroxy-butyl, hydroxy-pentyl, hydroxy-hexyl, hydroxy-octyl, hydroxy-nonyl, and hydroxy-decyl.

In one embodiment, the curable composition of the present invention comprises:
(A) 97% to 99.5% by weight of at least one component containing an ethylenically unsaturated group, wherein component (A) comprises a component (A1) containing a structure (K) selected from an isocyanurate structure and/or a tricyclodecane ring structure; and
(B) 0.1% to 3% by weight of at least one photo-initiator, wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
   wherein component (A1) comprises or is a tri(meth)acrylate of tris(hydroxy-C₁₋₃₀-alkyl) isocyanurates,
   the hydroxy-C₁₋₃₀-alkyl of the tri(meth)acrylate of tris(hydroxy-alkyl) isocyanurates is selected from hydroxy-methyl, hydroxy-ethyl, hydroxy-propyl, hydroxy-butyl, hydroxy-pentyl, hydroxy-hexyl, hydroxy-octyl, hydroxy-nonyl, hydroxy-decyl, hydroxy-C₁₁-alkyl, hydroxy-C₁₂-alkyl, hydroxy-C₁₃-alkyl, hydroxy-C₁₄-alkyl, hydroxy-C₁₅-alkyl, hydroxy-C₁₆-alkyl, hydroxy-C₁₇-alkyl, hydroxy-C₁₈-alkyl, hydroxy-C₁₉-alkyl, hydroxy-C₂₀-alkyl, hydroxy-C₂₁-alkyl, hydroxy-C₂₂-alkyl, hydroxy-C₂₃-alkyl, hydroxy-C₂₄-alkyl, hydroxy-C₂₅-alkyl, hydroxy-C₂₆-alkyl, hydroxy-C₂₇-alkyl, hydroxy-C₂₃-alkyl, hydroxy-C₂₉-alkyl, hydroxy-C₃₀-alkyl, preferably selected from hydroxy-methyl, hydroxy-ethyl, hydroxy-propyl, hydroxy-butyl, hydroxy-pentyl, hydroxy-hexyl, hydroxy-octyl, hydroxy-nonyl, and hydroxy-decyl.

In one embodiment, the curable composition of the present invention comprises:
(A) 80% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 8% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
wherein component (A1) comprises or is a tricyclodecane-di-C₁₋₂₀-alkanol di(meth)acrylate, such as tricyclodecanedi-methanol di(meth)acrylate,
tricyclodecanedi-ethanol di(meth)acrylate, tricyclodecanedi-propanol di(meth)acrylate,
tricyclodecanedi-butanol di(meth)acrylate, tricyclodecanedi-pentanol di(meth)acrylate,
tricyclodecanedi-C₆-alkanol di(meth)acrylate, tricyclodecanedi-C₇-alkanol di(meth)acrylate, tricyclodecanedi-C₃-alkanol di(meth)acrylate,
tricyclodecanedi-C₉-alkanol di(meth)acrylate, tricyclodecanedi-C₁₀-alkanol di(meth)acrylate, tricyclodecanedi-C₁₂-alkanol di(meth)acrylate,
tricyclodecanedi-C₁₄-alkanol di(meth)acrylate, tricyclodecanedi-C₁₆-alkanol di(meth)acrylate, tricyclodecanedi-C₁₈-alkanol di(meth)acrylate,
tricyclodecanedi-C₂₀-alkanol di(meth)acrylate, and any combination thereof.

In one embodiment, the curable composition of the present invention comprises:
(A) 90% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 5% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
wherein component (A1) comprises or is a tricyclodecane-di-C₁₋₂₀-alkanol di(meth)acrylate, such as tricyclodecanedi-methanol di(meth)acrylate,
tricyclodecanedi-ethanol di(meth)acrylate, tricyclodecanedi-propanol di(meth)acrylate,
tricyclodecanedi-butanol di(meth)acrylate, tricyclodecanedi-pentanol di(meth)acrylate,
tricyclodecanedi-C₆-alkanol di(meth)acrylate, tricyclodecanedi-C₇-alkanol di(meth)acrylate, tricyclodecanedi-C₃-alkanol di(meth)acrylate,
tricyclodecanedi-C₉-alkanol di(meth)acrylate, tricyclodecanedi-C₁₀-alkanol di(meth)acrylate, tricyclodecanedi-C₁₂-alkanol di(meth)acrylate,
tricyclodecanedi-C₁₄-alkanol di(meth)acrylate, tricyclodecanedi-C₁₆-alkanol di(meth)acrylate, tricyclodecanedi-C₁₈-alkanol di(meth)acrylate,
tricyclodecanedi-C₂₀-alkanol di(meth)acrylate, and any combination thereof.

In one embodiment, the curable composition of the present invention comprises:
(A) 97% to 99.5% by weight of at least one component containing an ethylenically unsaturated group, wherein component (A) comprises a component (A1) containing a structure (K) selected from an isocyanurate structure and/or a tricyclodecane ring structure; and
(B) 0.1% to 3% by weight of at least one photo-initiator, wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
wherein component (A1) comprises or is a tricyclodecane-di-C₁₋₂₀-alkanol di(meth)acrylate, such as tricyclodecanedi-methanol di(meth)acrylate,
tricyclodecanedi-ethanol di(meth)acrylate, tricyclodecanedi-propanol di(meth)acrylate,
tricyclodecanedi-butanol di(meth)acrylate, tricyclodecanedi-pentanol di(meth)acrylate,
tricyclodecanedi-C₆-alkanol di(meth)acrylate, tricyclodecanedi-C₇-alkanol di(meth)acrylate, tricyclodecanedi-C₃-alkanol di(meth)acrylate,
tricyclodecanedi-C₉-alkanol di(meth)acrylate, tricyclodecanedi-C₁₀-alkanol di(meth)acrylate, tricyclodecanedi-C₁₂-alkanol di(meth)acrylate,
tricyclodecanedi-C₁₄-alkanol di(meth)acrylate, tricyclodecanedi-C₁₆-alkanol di(meth)acrylate, tricyclodecanedi-C₁₈-alkanol di(meth)acrylate,
tricyclodecanedi-C₂₀-alkanol di(meth)acrylate, and any combination thereof.

In one embodiment, the curable composition of the present invention comprises:
(A) 80% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 8% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
wherein component (A1) comprises or is tri(meth)acrylate of tris-(2-hydroxyethyl)isocyanurate, tri(meth)acrylate of tris(hydroxymethyl)isocyanurate,
tri(meth)acrylate of tris(3-hydroxy-n-propyl)isocyanurate, tricyclodecanedi-methanol di(meth)acrylate, tricyclodecanedi-ethanol di(meth)acrylate,
tricyclodecanedi-propanol di(meth)acrylate, tricyclodecanedi-butanol di(meth)acrylate,
tricyclodecanedi-pentanol di(meth)acrylate, tricyclodecanedi-C₆-alkanol di(meth)acrylate, tricyclodecanedi-C₇-alkanol di(meth)acrylate,
tricyclodecanedi-C₃-alkanol di(meth)acrylate, tricyclodecanedi-C₉-alkanol di(meth)acrylate, tricyclodecanedi-C₁₀-alkanol di(meth)acrylate, or any combination thereof.

In one embodiment, the curable composition of the present invention comprises:
(A) 90% to 99.9% by weight of at least one component containing an ethylenically unsaturated group, wherein component (A) comprises a component (A1) containing a structure (K) selected from an isocyanurate structure and/or a tricyclodecane ring structure; and
(B) 0.1% to 5% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
wherein component (A1) comprises or is tri(meth)acrylate of tris-(2-hydroxyethyl)isocyanurate, tri(meth)acrylate of tris(hydroxymethyl)isocyanurate,
tri(meth)acrylate of tris(3-hydroxy-n-propyl)isocyanurate, tricyclodecanedi-methanol di(meth)acrylate, tricyclodecanedi-ethanol di(meth)acrylate,
tricyclodecanedi-propanol di(meth)acrylate, tricyclodecanedi-butanol di(meth)acrylate,
tricyclodecanedi-pentanol di(meth)acrylate, tricyclodecanedi-C₆-alkanol di(meth)acrylate, tricyclodecanedi-C₇-alkanol di(meth)acrylate,
tricyclodecanedi-C₃-alkanol di(meth)acrylate, tricyclodecanedi-C₉-alkanol di(meth)acrylate, tricyclodecanedi-C₁₀-alkanol di(meth)acrylate, or any combination thereof.

In one embodiment, the curable composition of the present invention comprises:
(A) 97% to 99.5% by weight of at least one component containing an ethylenically unsaturated group, wherein component (A) comprises a component (A1) containing a structure (K) selected from an isocyanurate structure and/or a tricyclodecane ring structure; and
(B) 0.1% to 3% by weight of at least one photo-initiator,
wherein the amount of component (A1) is in the range from 10% to 90% by weight, preferably from 15% to 85% by weight, more preferably from 20% to 80% by weight, based on the total amount of component (A),
wherein the average glass transition temperature (Tg,av) calculated from the curable composition using the following Fox's equation is at least 373.15K, preferably at least 393.15K, more preferably at least 423.15K:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A),
wherein component (A1) comprises or is tri(meth)acrylate of
tris-(2-hydroxyethyl)isocyanurate, tri(meth)acrylate of tris(hydroxymethyl)isocyanurate,
tri(meth)acrylate of tris(3-hydroxy-n-propyl)isocyanurate, tricyclodecanedi-methanol
di(meth)acrylate, tricyclodecanedi-ethanol di(meth)acrylate,
tricyclodecanedi-propanol di(meth)acrylate, tricyclodecanedi-butanol di(meth)acrylate,
tricyclodecanedi-pentanol di(meth)acrylate, tricyclodecanedi-C₆-alkanol
di(meth)acrylate, tricyclodecanedi-C₇-alkanol di(meth)acrylate,
tricyclodecanedi-C₈-alkanol di(meth)acrylate, tricyclodecanedi-C₉-alkanol
di(meth)acrylate, tricyclodecanedi-C₁₀-alkanol di(meth)acrylate, or any combination thereof.

### Component (C)

For practical applications, optionally, the curable composition of the present invention may further comprise auxiliary agents as component (C).

As auxiliary agents, mention may be made by way of preferred example of surfactants, flame retardants, dyes, pigments, catalyst, UV absorbers and stabilizers, e.g. against oxidation, hydrolysis, light, heat or discoloration, inorganic and/or organic fillers, and reinforcing materials. As hydrolysis inhibitors, preference is given to oligomeric and/or polymeric aliphatic or aromatic carbodiimides. To stabilize the cured material of the invention against aging and damaging environmental influences, stabilizers are added to system in preferred embodiments.

Surfactants are surface active compounds, such as anionic, cationic, nonionic and amphoteric surfactants, and mixtures thereof. Such surfactants can be used for example as dispersant, solubilizer, and the like. Examples of surfactants are listed in McCutcheon's, Vol. 1: Emulsifiers & Detergents, McCutcheon's Directories, Glen Rock, USA, 2008 (International Ed. or North American Ed.). Suitable anionic surfactants may be alkali, alkaline earth or ammonium salts of sulfonates, sulfates, phosphates, carboxylates, and mixtures thereof. Suitable nonionic surfactants may be alkoxylates, N-substituted fatty acid amides, amine oxides, esters, sugar-based surfactants, polymeric surfactants, and mixtures thereof. Suitable cationic surfactants may be quaternary surfactants, for example quaternary ammonium compounds with one or two hydrophobic groups, or salts of long chain primary amines. Suitable amphoteric surfactants may be alkylbetains and imidazolines.

Further details regarding the abovementioned auxiliary agents may be found in the specialist literature, e.g. in Plastics Additive Handbook, 5th edition, H. Zweifel, ed, Hanser Publishers, Munich, 2001.

When present, the amount of component (C) in the curable composition of the present invention may be in the range from 0 to 18% by weight, for example 1% by weight, 3% by weight, 5% by weight, 7% by weight, 9% by weight, 11% by weight, 13% by weight, 15% by weight, 17% by weight, 18% by weight, preferably from 0 to 16% by weight, or from 0 to 15% by weight, or from 0 to 13% by weight, or from 0 to 10% by weight, based on the total weight of the curable composition of the present invention.

### Preparation of the Composition

One aspect of the present invention relates to a process of preparing the curable composition of the present invention for 3D-printing, comprising mixing the components of the composition.

According to an embodiment of the invention, the mixing can be carried out at a temperature in the range from room temperature to about 80° C. with stirring, such as at a temperature in the range from 30° C. to about 80° C., preferably 40° C. to about 60° C., for example about 50° C. There is no particular restriction on the time of mixing and rate of stirring, as long as all components are uniformly mixed together. In a specific embodiment, the mixing can be carried out at 1000 to 3000 RPM, preferably 1500 to 2500 RPM for 5 to 60 min, more preferably 6 to 30 min.

### 3D-Printed Object and Preparation Thereof

One aspect of the present invention relates to a process of forming 3D-printed object, comprising using the curable composition of the present invention.

In one embodiment of the present invention, the process of forming a 3D-printed object comprises the steps of:
(i) applying the curable composition, and curing the applied curable composition layer by layer by radiation to form an intermediate 3D-printed object; and
(ii) curing the whole intermediate 3D-printed object by radiation to form a cured 3D-printed object.

According to the invention, the curing time in step (i) and (ii) may be determined respectively by a skilled person according to practical application. For example, in step (i) of the process, the curing time for each layer may be from 0.5 to 15 s, such as from 1 to 10 s.

In step (ii) of the process, the curing time for the whole intermediate 3D-printed object may be in the range from 3 min to 500 min, for example 3 min, 5 min, 10 min, 20 min, 30 min, 40 min, 60 min, 80 min, 100 min, 120 min, 180 min, 250 min, 300 min, 400 min, preferably from 10 min to 250 min.

There is no specific restriction on the temperature during step (i) or step (ii).

Specifically, the temperature may be selected depending on the material and the 3D printer used.

Radiation used in steps (i) and (ii) of the process of forming a 3D-printed object of the present invention may be adopted by a skilled person according to the practical 3D-printing applications. For example, the radiation may be actinic ray that has sufficient energy to initiate a polymerization or cross-linking reaction. The actinic ray can include but is not limited to α-rays, γ-rays, ultraviolet radiation (UV radiation), visible light, and electron beams, wherein UV radiation and electron beams, especially, UV radiation is preferred.

In a specific embodiment, the wavelength of the radiation light can be in the range from 350 to 480 nm, for example 355 nm, 365 nm, 385 nm, 395 nm, 405 nm, 420 nm, 440 nm, 460 nm, 480 nm.

Stereolithography (SLA), digital light processing (DLP), photopolymer jetting (PPJ), LCD technology or other techniques known by a person skilled in the art can be employed in step (i) of the process of forming 3D-printed objects of the present invention. Preferably, the production of cured 3D objects of complex shape is performed for instance by means of stereolithography, which has been known for a number of years. In this technique, the desired shaped article is built up from a radiation-curable composition with the aid of a recurring, alternating sequence of two steps (1) and (2). In step (1), a layer of the radiation-curable composition, one boundary of which is the surface of the composition, is cured with the aid of appropriate imaging radiation, preferably imaging radiation from a computer-controlled scanning laser beam, within a surface region which corresponds to the desired cross-sectional area of the shaped article to be formed, and in step (2) the cured layer is covered with a new layer of the radiation-curable composition, and the sequence of steps (1) and (2) is often repeated until the desired shape is finished.

The present invention further relates to a 3D-printed object formed from the curable composition of the present invention or obtained by the process of the present invention.

Non-limiting examples of the 3D-printed objects of the present invention comprise plastic parts within a vehicle, such as interior parts, connectors and functional prototypes.

### EXAMPLES

The present invention will be better understood in view of the following non-limiting examples.

### Materials and Abbreviation

| Component | Materials | Description |
|---|---|---|
| Component | Sartomer SR368 | Tris (2-hydroxy ethyl) |
| (A1) | | isocyanurate triacrylate, |
| | | available from Sartomer |
| | | Co., Exton, PA |
| | Sartomer SR833S | Tricyclodecane dimethanol |
| | | diacrylate, available from |
| | | Sartomer Co., Exton, PA |
| Component | Rahn Genomer 4247 | Aliphatic urethane |
| (A2) | | dimethacrylate, available |
| | | from Rahn |
| | Dymax BR952 | Aliphatic urethane |
| | | dimethacrylate, available |
| | | from Dymax |
| | Acryloylmorpholine | available from Rahn |
| | (ACMO) | |
| | Isobornyl | available from Miwon |
| | Methacrylate (IBOMA) | |
| Photo-initiator | Omnirad TPO-L | Ethyl(2,4,6-trimethylbenzoyl)- |
| (B) | | phenyl phosphonate, available |
| | | from IGM |

### Methods

### (1) Heat Deflection Temperature (HDT)

Heat deflection temperature was determined in accordance with ASTM D648-07.

### (2) Average Tg (Tg,av)

The average glass transition temperature (Tg,av) in examples was calculated using the following Fox's equation:

$$\frac{1}{{T}_{g , av}} = \sum \frac{{w}_{i}}{{T}_{g , i}}$$

wherein Tg,i is the glass transition temperature in Kelvin of the homopolymer of component (i) constituting component (A), and w; is the mass fraction of component (i) in component (A).

### Examples 1

Curable compositions 1-5 were prepared by adding all components listed in Table 1 in amounts as shown in Table 2 into a plastic vial and mixing by speed-mixer at 2000 RPM for 10 minutes at 50° C. to obtain the liquid curable compositions.

Curable compositions 1-5 were printed using a MiiCraft 150 3D printer respectively, which was a desktop Digital Light Processing (DLP) 3D printer with light wavelength at 405 nm. For a typical printing process, a curable composition was loaded into a vat within the printer. Detailed printing parameters were summarized as follows: UV energy 4.75 mW/cm², base curing time 6.0 s, base layer 1, curing time 2.0 s, buffer layer 5.

After the 3D printing process, the obtained object was soaked in ethanol and shook for 10 seconds to remove uncured materials on the surface, followed by being dried using compressed air. A final object with smooth-dry surface was obtained after being UV post-cured for 40 minutes using a NextDent post-curing unit (LC-3DPrint box).

HDT of the final object prepared from each composition was provided in table 2.

Mechanical properties of the final object prepared from each composition were provided in table 3.

TABLE 1
Components of curable compositions 1-5

| | Tg of homopolymer of each component |
|---|---|
| Components | Tg (K) |
| Sartomer SR368 | 543 |
| ACMO | 418 |
| Omnirad tpo-l | N/A |

TABLE 2
Curable compositions 1-5 and corresponding
HDT and average Tg (Tg, av)

| | ACMO | SR368 | TPO-L | Tg, av | HDT @ 1.82 |
|---|---|---|---|---|---|
| Compositions | (g) | (g) | (g) | (K) | MPa (° C.) |
| 1 | 40 | 60 | 1 | 484.60 | 171 |
| 2 | 65 | 35 | 1 | 454.01 | 143 |
| 3 | 70 | 30 | 1 | 448.35 | 136 |
| 4 | 75 | 25 | 1 | 442.83 | 131 |
| 5 | 80 | 20 | 1 | 437.44 | 125 |

TABLE 3
Mechanical properties

| | Young's modulus | Tensile strength | Strain at break |
|---|---|---|---|
| Compositions | (MPa) | (MPa) | (%) |
| 1 | 3630 | 61.5 | 2.80 |
| 2 | 3570 | 82.8 | 3.34 |
| 3 | 3486 | 65.3 | 2.76 |
| 4 | 3730 | 85.8 | 3.16 |
| 5 | 3887 | 79.4 | 2.70 |

### Example 2

Curable compositions 6-7 and comparative composition 1 were prepared by adding all components listed in Table 4 in amounts as shown in Table 5 into a plastic vial and mixing by speed-mixer at 2000 RPM for 10 minutes at 50° C. to obtain the liquid curable compositions.

Curable compositions 6-7 and comparative composition 1 were printed using a MiiCraft 150 3D printer respectively, which was a desktop Digital Light Processing (DLP) 3D printer with light wavelength at 405 nm. For a typical printing process, a curable composition was loaded into a vat within the printer. Detailed printing parameters were summarized as follows: UV energy 4.75 mW/cm², base curing time 6.0 s, base layer 1, curing time 2.0 s, buffer layer 5.

After the 3D printing process, the obtained object was soaked in ethanol and shook for 10 seconds to remove uncured materials on the surface, followed by being dried using compressed air. A final object with smooth-dry surface was obtained after being UV post-cured for 40 minutes using a NextDent post-curing unit (LC-3DPrint box).

HDT of the final object prepared from each composition was provided in table 5.

Mechanical properties of the final object prepared from each composition were provided in table 6.

TABLE 4
Components of curable compositions
6-7 and comparative composition 1

| | Tg of homopolymer of each component |
|---|---|
| Components | Tg (K) |
| Sartomer SR368 | 543 |
| Rahn Genomer 4247 | 407 |
| Dymax BR952 | 432 |
| ACMO | 418 |
| IBOMA | 423 |
| Omnirad tpo-l | N/A |

TABLE 5
Curable compositions 6-7, comparative composition 1, and corresponding
HDT and average Tg (Tg,av)

| | | | | | | | | HDT |
|---|---|---|---|---|---|---|---|---|
| | | Dymax | | | | | | @ 1.82 |
| | Genomer | BR952 | ACMO | IBOMA | SR368 | TPO-L | Tg,av | MPa |
| Compositions | 4247 (g) | (g) | (g) | (g) | (g) | (g) | (K) | (° C.) |
| 6 | 20 | 0 | 40 | 10 | 30 | 1 | 446.67 | 112.2 |
| 7 | 0 | 25 | 30 | 15 | 30 | 1 | 453.15 | 140.2 |
| comparative | 35 | 10 | 40 | 15 | 0 | 1 | 415.9 | 92 |
| composition 1 | | | | | | | | |

TABLE 6
Mechanical properties

| | Young's modulus | Tensile strength | Strain at break |
|---|---|---|---|
| Compositions | (MPa) | (MPa) | (%) |
| 6 | 3897 | 98.3 | 4.6 |
| 7 | 3640 | 92.9 | 5.0 |
| comparative | 2882 | 87.1 | 6.6 |
| composition 1 | | | |

### Example 3

Curable compositions 8-11 were prepared by adding all components listed in Table 7 in amounts as shown in Table 8 into a plastic vial and mixing by speed-mixer at 2000 RPM for 10 minutes at 50° C. to obtain the liquid curable compositions.

Curable compositions 8-11 were printed using a MiiCraft 150 3D printer respectively, which was a desktop Digital Light Processing (DLP) 3D printer with light wavelength at 405 nm. For a typical printing process, a curable composition was loaded into a vat within the printer. Detailed printing parameters were summarized as follows: UV energy 4.75 mW/cm², base curing time 6.0 s, base layer 1, curing time 2.0 s, buffer layer 5.

After the 3D printing process, the obtained object was soaked in ethanol and shook for 10 seconds to remove uncured materials on the surface, followed by being dried using compressed air. A final object with smooth-dry surface was obtained after being UV post-cured for 40 minutes using a NextDent post-curing unit (LC-3DPrint box).

HDT of the final object prepared from each composition was provided in table 8.

TABLE 7
Components of curable compositions 8-11

| | Tg of homopolymer of each component |
|---|---|
| Components | Tg (K) |
| Sartomer SR833S | 458 |
| ACMO | 418 |
| Omnirad tpo-l | N/A |

TABLE 8
Curable compositions 8-11 and corresponding
HDT and average Tg (Tg, av)

| | ACMO | SR833S | TPO-L | Tg, av | HDT @ 1.82 |
|---|---|---|---|---|---|
| Compositions | (g) | (g) | (g) | (K) | MPa (° C.) |
| 8 | 20 | 80 | 1 | 449.35 | 111 |
| 9 | 40 | 60 | 1 | 440.85 | 111 |
| 10 | 60 | 40 | 1 | 432.65 | 110 |
| 11 | 80 | 20 | 1 | 424.75 | 107 |

### Example 4

Curable composition 12 was prepared by adding all components listed in Table 9 in amounts as shown in Table 10 into a plastic vial and mixing by speed-mixer at 2000 RPM for 10 minutes at 50° C. to obtain the liquid curable compositions.

Curable composition 12 was printed using a MiiCraft 150 3D printer, which was a desktop Digital Light Processing (DLP) 3D printer with light wavelength at 405 nm. For a typical printing process, curable composition 12 was loaded into a vat within the printer. Detailed printing parameters were summarized as follows: UV energy 4.75 mW/cm², base curing time 6.0 s, base layer 1, curing time 2.0 s, buffer layer 5.

After the 3D printing process, the obtained object was soaked in ethanol and shook for 10 seconds to remove uncured resin on the surface, followed by being dried using compressed air. A final object with smooth-dry surface was obtained after being UV post-cured for 40 minutes using a NextDent post-curing unit (LC-3DPrint box).

HDT of the final object prepared from composition 12 was provided in table 10.

Mechanical properties of the final object prepared from composition 12 were provided in table 11.

TABLE 9
Components of curable composition 12

| | Tg of homopolymer of each component |
|---|---|
| Components | Tg (K) |
| Sartomer SR368 | 543 |
| Sartomer SR833S | 458 |
| ACMO | 418 |
| Omnirad tpo-l | N/A |

TABLE 10
Curable composition 12 and corresponding HDT and average
Tg (Tg,av)

| | | | | | | HDT |
|---|---|---|---|---|---|---|
| | | | | | | @ 1.82 |
| | ACMO | SR368 | SR833S | TPO-L | Tg,av | MPa |
| Composition | (g) | (g) | (g) | (g) | (K) | (° C.) |
| 12 | 20 | 40 | 40 | 1 | 478.75 | 196 |

TABLE 11
Mechanical properties

| | Young's modulus | Tensile strength | Strain at |
|---|---|---|---|
| Composition | (MPa) | (MPa) | break (%) |
| 12 | 3914 | 66.4 | 1.9 |

1.-18. (canceled)

19. A curable composition, which comprises:
(A) at least one component containing an ethylenically unsaturated group, wherein component (A) comprises a component (A1) containing a structure (K) selected from an isocyanurate structure and/or a tricyclodecane ring structure; and
(B) at least one photo-initiator,
wherein the average glass transition temperature (Tg,av) calculated from the curable composition using the following Fox's equation is at least 373.15K:
$$\frac{1}{{T}_{g , av}} = \sum \frac{{w}_{i}}{{T}_{g , i}}$$
wherein Tg,i is the glass transition temperature in Kelvin of the homopolymer of component (i) constituting component (A), and w, is the mass fraction of component (i) in component (A).

20. The curable composition according to claim 19, wherein component (A1) contains at least 1 ethylenically unsaturated groups.

21. The curable composition according to claim 19, wherein the ethylenically unsaturated group is selected from the group consisting of allyl, vinyl, acrylate, methacrylate, acryloxy, methacryloxy, acrylamido, methacrylamido, acetylenyl, and maleimido.

22. The curable composition according to claim 19, wherein component (A1) comprises or is a tri(meth)acrylate of tris(hydroxy-C₁₋₃₀-alkyl) isocyanurates.

23. The curable composition according to claim 19, wherein component (A1) comprises or is a tricyclodecane-di-C₁₋₂₀-alkanol di(meth)acrylate.

24. The curable composition according to claim 19, wherein the photo-initiator is a free radical photo-initiator and/or an ionic photo-initiator, preferably a free radical photo-initiator.

25. The curable composition of claim 19, wherein the amount of component (A) is in the range from 80% to 99.9% by weight, based on the total amount of the curable composition.

26. The curable composition according to claim 19, wherein the amount of component (A1) is in the range from 10% to 90% by weight, based on the total amount of component (A).

27. The curable composition according to claim 19, wherein the amount of the photo-initiator is in the range from 0.1% to 8% by weight, based on the total amount of the curable composition.

28. The curable composition according to claim 19, which further comprises an auxiliary agent as component (C), selected from the group consisting of surfactants, flame retardants, pigments, fillers, dyes, catalyst, UV absorbers and stabilizers, and reinforcing materials.

29. The curable composition according to claim 19, wherein the cured product formed from the curable composition has a HDT value of at least 100° C., at a load of 1.82 MPa, as measured according to the test standard ASTM D648-07.

30. The curable composition according to claim 19, wherein component (A) further comprises a component (A2) containing no structure (K).

31. A process of forming a 3D-printed object, comprising using the curable composition according to claim 19.

32. The process according to claim 31, comprising:
(i) applying the curable composition, and curing the applied curable composition layer by layer by radiation to form an intermediate 3D-printed object; and
(ii) curing the whole intermediate 3D-printed object by radiation to form a cured 3D-printed object.

33. The process according to claim 32, wherein stereolithography, photopolymer jetting, digital light processing, or LCD technology is used in step (i) to form the intermediate 3D-printed object.

34. The process according to claim 32, wherein the radiation is UV radiation.

35. A 3D-printed object formed from the curable composition according to claim 19.

36. The 3D-printed object according to claim 35, wherein the 3D-printed object comprises plastic parts within a vehicle.
